(19) United States
(12) Patent Application Publication
(10) Pub. No.: US 2018/0067506 A1
(43) Pub. Date: Mar. 8, 2018

(54) MODULES TO POWER AND CONTROL PUMPS

(71) Applicant: HEWLETT PACKARD ENTERPRISE DEVELOPMENT LP, Houston, TX (US)

(72) Inventors: Charles R. HANNA, Houston, TX (US); Tahir CADER, Liberty Lake, WA (US); John FRANZ, Houston, TX (US)

(21) Appl. No.: 15/258,871

(22) Filed: Sep. 7, 2016

(51) Int. Cl. G05D 7/06; H05K 7/20; G06F 1/20; H01R 12/72; H01R 12/71; H01R 24/60

(52) U.S. Cl. CPC G05D 7/0676; H05K 7/20272; G06F 1/20; H01R 2107/00; H01R 12/716; H01R 24/60; H01R 12/721

(57) ABSTRACT

Examples include a module to power and control a pump to cool an electronic module. The module comprises an electronic module connector to connect to a printed circuit assembly of the electronic module. The connector transmits power to provide power to the pump and a control signal to control the pump. A controller may be electrically connected to the electronic module connector to receive the control signal to control the pump. The module may also comprise a first supply connector to connect to a first supply fluid line to provide fluid to the pump and a first return connector to connect to a first return fluid line to receive fluid from the pump. The module may also include a second supply connector to connect to a second supply fluid line and a second return connector to connect to a second return fluid line.

### BACKGROUND

Electrical components and devices often generate heat. Accordingly, electronic modules, such as servers, may use a cooling mechanism to reduce the thermal impact of the generated heat and to achieve optimum performance. Some electronic modules utilize fan-based cooling. Others utilize pump-based cooling.

### BRIEF DESCRIPTION OF THE DRAWINGS

The following detailed description references the drawings, wherein:

FIG. 1 is a perspective view of an example module to power and control a pump to cool an electronic module;

FIG. 2 is a perspective view of an example module to power and control a pump comprising a pump connector and a leak detection connector;

FIG. 3 is a block diagram an example pump module comprising an electrical module connector, a pump, and a controller;

FIG. 4 is a block diagram an example pump module wherein a pump outlet is connected to a return connector via a return fluid line and a pump inlet is connected to a supply connector via supply fluid line;

FIG. 5 is a flowchart of an example method of powering and controlling a pump to cool an electronic module via a module including providing power to the pump via an electronic module connector and a pump connector and controlling the pump via a controller on the pump; and

FIG. 6 is a flowchart of an example method of powering and controlling a pump to cool an electronic module via a module including receiving a control signal at a controller on the module from a remote management controller to control the pump.

### DETAILED DESCRIPTION

Electronic modules comprising electronic devices and components may use a variety of cooling mechanisms to counteract heat generated by the electronic devices and components. Some electronic modules may use fan-based cooling systems. Other electronic modules may use thermo-electric cooling systems. Yet other electronic modules may use pump-based cooling systems.

In some examples, cooling systems may use dedicated system-specific connectors to connect to an electronic module that may be used to power or control the cooling system. For instance, a fan-based cooling system may use a fan-specific connector on a printed circuit assembly of the electronic module to power or control the fan. Likewise, a thermo-electric based or pump-based cooling system may use a thermo-electric specific connector or a pump-specific connector on a printed circuit assembly of the electronic module to power or control the cooling system. Such cooling system-specific connectors, however, may occupy valuable real estate on the printed circuit assembly and may involve dedicated printed circuit assemblies directed to a specific cooling system, which may result in a more inflexible and cost-inefficient electronic module.

In some examples, system-specific connectors may lead to an inflexible arrangement that is not readily amenable to different types of cooling. For instance, a fan-based cooling system utilizing fan-specific connectors may be prohibitively cost-intensive and/or labor-intensive to transition to a pump-based cooling system. In some such examples, the fan-specific connector may be used to provide power to the pump-based cooling system. However, using fan-specific connectors to power a pump-based cooling system may be inefficient and ineffective for certain types of pumps and pump-based systems.

Examples described herein may allow for more efficient use of valuable printed circuit assembly real estate for a pump-based cooling system and may improve flexibility between various types of cooling systems for an electronic module. Examples described herein may also allow for centralized control of multiple pumps within a pump-based cooling system.

In some examples described herein, a module to power and control a pump to cool an electronic module may comprise an electronic module connector to connect to a printed circuit assembly of the electronic module. The electronic module connector transmits power to provide power to the pump and a control signal to control the pump. The module also includes a controller that is electrically connected to the electronic module connector to receive the control signal to control the pump. The module further includes a first supply connector on the module connects to a first supply fluid line to provide fluid to the pump. The module also includes a first return connector to connect a first return fluid line and to receive fluid from the pump. In addition, the module includes a second supply connector to connect to a second supply fluid line and a second return connector to connect to a second return fluid line. In some examples, the electronic module connector may be a peripheral component interconnect (PCI) connector or a universal serial bus (USB) connector. In other examples, the controller may receive the control signal from a remote management controller on the electronic module that coordinates control of multiple pumps. In yet other examples, the module may include a pump connector to connect the module to the pump to provide power and the control signal to the pump.

In some examples described herein, a pump module to cool an electronic module may comprise an electronic module connector to connect to the electronic module where the electronic module connector is a PCI connector that connects to a corresponding PCI connector or a USB connector that connects to a corresponding USB connector on a printed circuit assembly of the electronic module. The pump module also comprises a pump that receives power via the electronic module connector, has a pump outlet for pumping fluid, and has a fi pump inlet for receiving fluid. The pump module also includes a supply connector to connect to a supply fluid line to provide fluid to the pump and a return connector to connect to a return fluid line and to receive fluid from the pump. The pump module further comprises a controller electrically connected to the electronic module connector to control the pump.

In some examples described herein, a method of powering and controlling a pump to cool an electronic module via a module may comprise connecting an electronic module connector on the module to the electronic module. The electronic module connector may be a PCI connector that connects to a corresponding PCI connector or a USB connector that connects to a corresponding USB connector on a printed circuit assembly of the electronic module. The method further comprises connecting a pump connector on the module to the pump and providing power to the pump via the electronic module connector and the pump connector. The method also includes controlling the pump by a controller on the module. The controller may be electronically connected to the electronic module connector and the pump connector. The method also includes providing fluid to the pump via a first supply fluid line, receiving fluid from the pump via a first return fluid line, providing fluid via a second supply fluid line, and receiving fluid via second return fluid line.

In some examples described herein, the method may further include monitoring information such as fluid flow rate, fluid temperature, fluid pressure, air temperature, and power consumption, by the controller on the module, sending the monitored information, by the controller on the module, to a remote management controller on the electronic module that coordinates control of multiple pumps, and receiving a control signal at the controller via the electronic module connector from the remote management controller to control the pump.

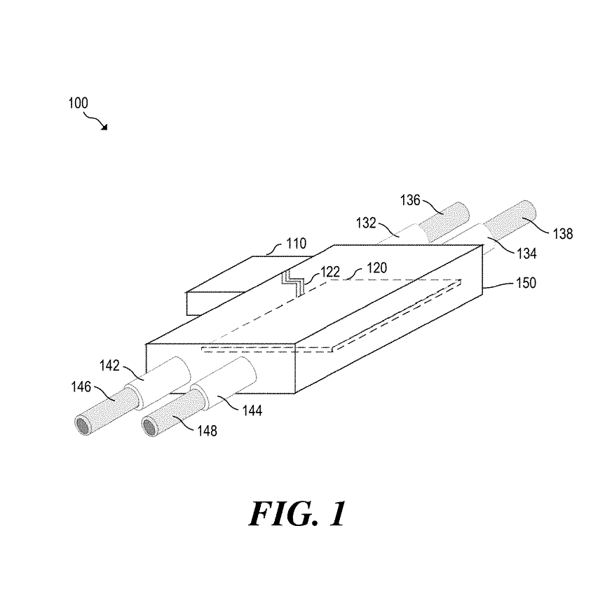

Referring now to the drawings, FIG. 1 is a perspective view of an example module 100 to power and control a pump to cool an electronic module (pump and electronic module not shown). As used herein, an electronic module refers to a computing device, such as a server, a blade server, or a server cartridge that provides computer solutions, storage solutions, network solutions, and/or cloud services. A pump, as used herein, refers to a device that uses suction and/or pressure to move fluid. In some examples, the pump may be a central processing unit (CPU) based pump that pumps fluid around electrical components such as a CPU to cool the components. As shown in FIG. 1, in some examples, module 100 may include a housing 150. Housing 150 may comprise a rigid or flexible plastic, metal, or other suitable material for housing or containing some or all of the components of module 100. In other examples, module 100 may not include a housing 150.

In the example of FIG. 1, module 100 has an electronic module connector 110. In the examples herein, an electronic module connector may refer to any mechanism for electrically and physically joining a module to an electrical module such that transmit power and control signals may be transmitted. In some examples, the electronic module connector may be a peripheral component interconnect (PCI) connector, a universal serial bus (USB) connector, or other suitable type of connector to transmit power and control signals. In some examples, use of a standardized connector for electronic module connector 110, such as a PCI connector or USB connector, that can connect to an off-the-shelf or standard printed circuit assembly of the electronic module may lower costs by reducing the need for a specialized printed circuit assembly and/or electronic module having a pump-specific connector. A standardized electronic module connector 110 may also reduce barriers to transitioning a fan-based or thermo-electric based cooling system for an electronic module to a pump-based cooling system by providing greater flexibility in connection mechanisms to the pump.

Electronic module connector 110 may be located on a lateral side of module 100, as depicted in FIG. 1. In other examples, however, electronic module connector 110 may be located at any suitable or convenient location of module 100. Electronic module connector 110 connects to a printed circuit assembly of the electronic module. A printed circuit assembly, as used in the examples herein, may refer to a printed circuit board that includes electrical components. A printed circuit board mechanically supports and electrically connects electronic components. In some such examples, an electronic module may include a server cartridge or server tray comprised of a printed circuit assembly. In some examples, the electronic module may have multiple printed circuit assemblies. The printed circuit assembly may include a number of standard connectors such as PCI and USB connectors to allow for connection to expansion cards or other devices that provided additional capabilities. In some examples, electronic module connector 110 may connect to or mate with a corresponding connector on the printed circuit assembly of the electronic module.

Electronic module connector 110 may receive power from the electronic module and transmit power to provide power to the pump. In some examples, electronic module connector 110 may include a dedicated power pin or pins to receive power from the electronic module. Electronic module connector 100 may also receive a control signal from the electrical module to control the pump. In some examples, the electronic module may generate the control signal to control the pump. In other examples, the electronic module may receive a control signal from another electronic module, from a central device in a data center, or from another device such as a remote device such as a smart phone or laptop to process and send to module 100 via the electronic module connector 110. Electronic module connector 110 may include a dedicated data or control pin or pins to receive control signals from the electronic module or to transmit information to the electronic module. The control signals may regulate pump speed, fluid flow, pump power, and the like.

As shown in the example of FIG. 1, module 100 further comprises controller 120. Electrical module connector 110 is electrically connected to controller 120. In some examples, as shown, electronic module connector 110 may be electrically connected to controller 120 via connection 122. Connection 122 may comprise a wire, cable, or other electrical connection to carry an electrical signal and to electrically connect electronic module connector 110 to controller 120. A controller, as used herein, may be at least one of a central processing unit (CPU), a semiconductor-based microprocessor, a graphics processing unit (GPU), a field-programmable gate array (FPGA) to retrieve and execute instructions, data, or control signals, other electronic circuitry suitable for the retrieval and execution of instructions, data, or control signals, or a combination thereof.

Controller 120 may receive a control signal from the electronic module via electronic module connector 110 to control the pump. As used herein, a control signal may comprise any electronic signal comprising data or other information used to control the pump. In some examples, the control signal may comprise data, commands, or instructions executable by the controller. Electronic module connector 110 may receive the control signal from the electrical module and transmit the control signal via connection 122 to controller 120. Controller 120 may receive the control signal and process, use and/or execute the control signal to control the pump. In some such examples, the control signal may regulate aspects of pump operation including, but not limited to, fluid flow rate, fluid pressure, pump speed, pump power, and the like.

In other examples, controller 120 may monitor the pump to track or detect information such as the fluid flow rate, the fluid temperature to and from the pump and the electronic module, the fluid pressure, an air temperature around the pump, the electronic module, or another device, the power consumption of the pump, or any combination thereof. In some such examples, controller 120 may periodically sense or otherwise determine the fluid flow rate, fluid temperature, fluid pressure, and/or air temperature at various locations within the fluid lines, and around the pump and electronic module. Controller 120 may also periodically determine the power consumption of the pump by tracking the power provided to the pump. In some examples, controller 120 may determine fluid flow rate, fluid temperature, fluid pressure, and pump power consumption via fluid flow rate sensors, temperature sensors, pressure sensors, power circuitry, and the like. Controller 120 may store the monitored information and provide it to the electronic module on demand or at certain intervals. In other such examples, controller 120 may analyze the monitored information and take certain actions based (at least in part) on the monitored information. For instance, a determination that the power consumption of the pump is unusually high over a certain period of time may prompt controller 120 to lower pump speed.

Module 100 may further comprise a first supply connector 132 to mechanically connect a first supply fluid line 136 to module 100. As used herein, a supply fluid line refers to a line that supplies fluid. In some examples, first supply fluid line 136 may be made of a rigid material. In other examples, first supply fluid line 136 may be made of a flexible material or other suitable material capable of carrying fluid. First supply fluid line 136 provides fluid to the pump. In some examples, first supply fluid line 136 may be routed around or adjacent to electrical components of the electrical module to cool the electrical components. In other examples, depending on an expected temperature of the fluid in the first supply fluid line 136, the line may be routed away from the electrical components of the electrical module.

A supply connector, as used herein, may refer to any mechanism that mechanically connects the module to a supply fluid line. In some examples, first supply connector 132 comprises a rigid connector that receives and mates with first supply fluid line 136 to connect first supply fluid line 136 to module 100. In other examples, first supply connector 132 comprises a flexible connector that connects module 100 to first supply fluid line 136. In some examples, first supply connector 132 may comprise a flange, groove, sweat, weld, or other suitable fitting option to connect to first supply fluid line 136 and module 100. First supply connector 132 allows for fluid to be provided to the pump via first supply fluid line 136.

In some examples, controller 120 may regulate or monitor a flow rate of fluid to the pump via first supply connector 132 or first supply fluid line 136. In other examples, controller 120 may regulate or monitor fluid temperature to the pump via first supply connector 132 or first supply fluid line 136.

Module 100 also comprises a first return connector 134 to mechanically connect a first return fluid line 138 to module 100. As used herein, a return fluid line refers to a line that returns fluid. In some examples, first return fluid line 138 may be made of a rigid material. In other examples, first return fluid line 138 may be made of a flexible material or other suitable material capable of carrying fluid. First return fluid line 138 returns fluid from the pump. In some examples, first return fluid line 138 may be routed around or adjacent to electrical components of the electrical module to cool the electrical components. In other examples, depending on an expected temperature of the fluid in the first return fluid line 138, the line may be routed away from the electrical components of the electrical module.

A return connector, as used herein, may refer to any mechanism that mechanically connects the module to a return fluid line. In some examples, first return connector 134 comprises a rigid connector that receives and mates with first return fluid line 138 to connect first return fluid line 138 to module 100. In other examples, first return connector 134 comprises a flexible connector that connects module 100 to first return fluid line 138. In some examples, first return connector 134 may comprise a flange, groove, sweat, weld, or other suitable fitting option to connect to first return fluid line 138 and module 100. First return connector 134 allows for fluid to be returned to the module via first return fluid line 138 from the pump.

In some examples, controller 120 may regulate or monitor a flow rate of fluid from the pump via first return connector 134 or first return fluid line 138. In other examples, controller 120 may regulate or monitor fluid temperature to the pump via first return connector 134 or first return fluid line 138.

Module 100 also comprises a second supply connector 144 to mechanically connect a second supply fluid line 148 to module 100. In some examples, second supply fluid line 148 may be made of a rigid material. In other examples, second supply fluid line 148 may be made of a flexible material or other suitable material capable of carrying fluid. In some examples, a second supply fluid line 148 may provide fluid to a heat exchanger. In some examples, second supply fluid line 148 may be routed around or adjacent to electrical components of the electrical module to cool the electrical components. In other examples, depending on an expected temperature of the fluid in the second supply fluid line 148, the line may be routed away from the electrical components of the electrical module.

Second supply connector 144, in some examples, may comprise a rigid connector that receives and mates with second supply fluid line 148 to connect second supply fluid line 148 to module 100. In other examples, second supply connector 144 comprises a flexible connector that connects module 100 to second supply fluid line 148. In some examples, second supply connector 144 may comprise a flange, groove, sweat, weld, or other suitable fitting option to connect to second supply fluid line 148 and module 100. Second supply connector 144 allows for fluid to be provided or supplied via second supply fluid line 148.

In some examples, controller 120 may regulate or monitor a flow rate of fluid via second supply connector 144 or second supply fluid line 148. In other examples, controller 120 may regulate or monitor fluid temperature via second supply connector 144 or second supply fluid line 148.

Module 100 also comprises a second return connector 142 to mechanically connect a second return fluid line 146 to module 100. In some examples, second return fluid line 146 may be made of a rigid material. In other examples, second return fluid line 146 may be made of a flexible material or other suitable material capable of carrying fluid. Second return fluid line 146 returns fluid to module 100. In some examples, second return fluid line 146 may return fluid from a heat exchanger. In some examples, second return fluid line 146 may be routed around or adjacent to electrical components of the electrical module to cool the electrical components. In other examples, depending on an expected temperature of the fluid in the second return fluid line 146, the line may be routed away from the electrical components of the electrical module.

In some examples, second return connector 142 comprises a rigid connector that receives and mates with second return fluid line 146 to connect second return fluid line 146 to module 100. In other examples, second return connector 142 comprises a flexible connector that connects module 100 to second return fluid line 146. In some examples, second return connector 142 may comprise a flange, groove, sweat, weld, or other suitable fitting option to connect to second return fluid line 146 and module 100. Second return connector 142 allows for fluid to be returned to the module via second return fluid line 146.

In some examples, controller 120 may regulate or monitor a flow rate of fluid via second return connector 142 or second return fluid line 146. In other examples, controller 120 may regulate or monitor fluid temperature via second return connector 142 or second return fluid line 146.

In some examples the fluid lines of module 100 may comprise a closed loop system. In one such example, first supply fluid line 136 may be routed through the pump and may return to module 100 as first return fluid line 138. First return fluid line 138 may traverse module 100 and exit module 100 as second supply fluid line 148. Second supply fluid line 148 may be routed through a cooling distribution unit that may include a heat exchanger and reservoir and return to module 100 as second return fluid line 146. In other examples, the fluid lines of module 100 may comprise an open loop system. In one such example, first supply fluid line 136 may be routed through the pump and return to module 100 as first return fluid line 138. First return fluid line 138 may traverse module 100 and exit module 100 as second supply fluid line 148. Second supply fluid line 148 may be routed to an open loop cooling tower and a second return fluid line 146 may be routed from the open loop cooling tower back to module 100. In yet other examples, the fluid lines of module 100 may comprise an isolated loop system.

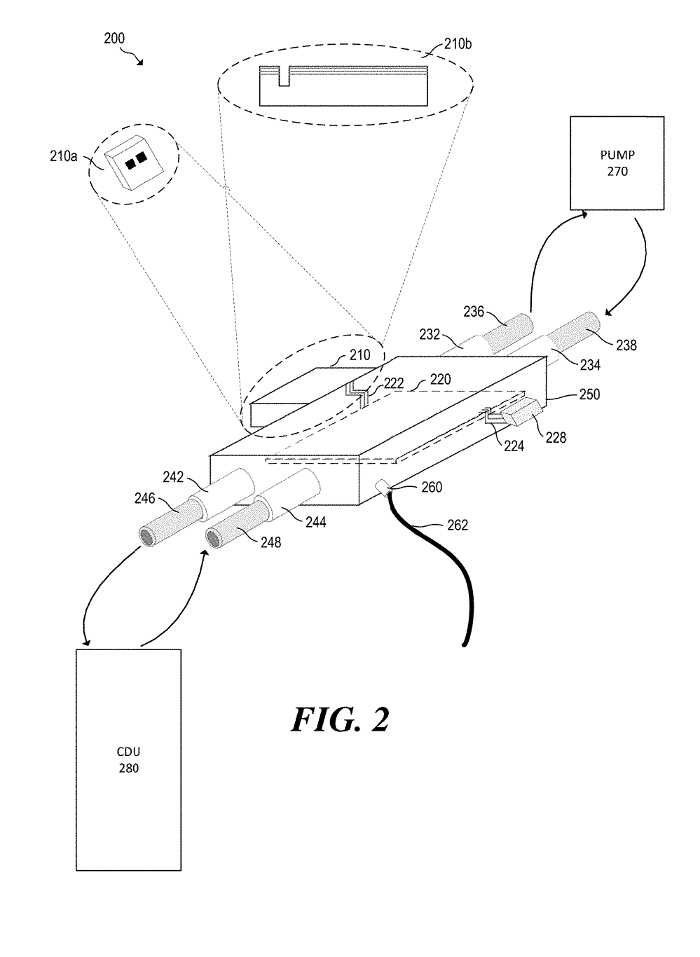

In some examples, the components and functionalities of module 100 of FIG. 1 may be provided in combination with the components and functionalities described herein in relation to any of FIGS. 2-6.

FIG. 2 further illustrates a perspective view of an example module 200 to power and control a pump 270 to cool an electronic module. In some examples, pump 270 may be located on the electronic module. In other examples, pump 270 may be located remotely from the electronic module.

Module 200 may include a housing 250, as described above in relation to housing 150 of FIG. 1. In other examples, module 200 may not include a housing 250. Module 200 may also comprise an electronic module connector 210, as described above in relation to electronic module connector 110 of FIG. 1. In the example of FIG. 2, electronic module connector 210 may comprise a USB connector 210a or a PCI connector 210b. USB connector 210a may mate with a corresponding USB connector on a printed circuit assembly of the electronic module via a USB cable. Similarly, PCI connector 210b may mate with a corresponding PCI connector on the printed circuit assembly of the electronic module 280. As described above in relation to electronic module connector 110 of FIG. 1, electronic module connector 210 of FIG. 2 may receive power from electronic module 280 and provide power to pump 270. Electronic module connector 210, like electronic module connector 110, may also receive and transmit a control signal.

Module 200 further comprises a controller 220, as described above in relation to controller 120 of FIG. 1. Electronic module connector 210 is electrically connected to controller 220. In some examples, as shown, electronic module connector 210 may be electrically connected to controller 220 via connection 222, as described above in relation to connection 122 of FIG. 1. Controller 220 may receive a control signal via electronic module connector 210 to control pump 270, as described above in relation to FIG. 1. In some examples, the control signal may be passed via electronic module controller 210 to controller 220 by way of connection 222. In some such examples, controller 220 may process the control signal and transmit the processed control signal to pump 270.

In some examples, as described above in relation to FIG. 1, the control signal may regulate pump speed, fluid flow, pump power, and the like. Controller 220 may also monitor pump 270 and the fluid lines to track or detect information such as the fluid flow rate, the fluid temperature, or the fluid pressure in the fluid lines. In some examples, controller 220 may also monitor or check an air temperature at various locations such as around pump 270, module 200, the electronic module, or any other suitable locations. In other examples, controller 220 may also monitor the power consumption of pump 270 or other pumps. In yet other examples, controller 220 may perform any combination thereof.

Controller 220 may, in some examples, may regulate pump speed or fluid flow rate by varying the power provided to pump 270. In other examples, controller 220 may regulate fluid temperature by increasing or decreasing fluid pressure or flow rate. In other examples, controller 220 may send any monitored information to the electronic module, to a remote management controller on the electronic module, or to any other suitable device or application. Controller 220 may send this information via electronic module connector 210. In other examples, controller 220 may generate a control signal based (at least in part) on the monitored information and send the control signal to pump 270 via connection 224 and pump connector 228.

A remote management controller, as used herein, may refer to a controller that controls a pump remotely. In some such examples, a remote management controller may allow for control of pump 270 and/or components on the electronic module via a remote interface. In some examples, a remote interface may be geographically remote from electronic module 280 such as a web interface accessed via a computing device in a location different from that of the electronic module. In other examples, remote interface may also be a centralized interface located proximate to, but not part of, the electronic module.

Controller 220, in some examples, may receive a control signal from the remote management controller on the electronic module. In some such examples, the control signal may be based (at least in part) on information monitored by controller 220 and sent to the electronic module and/or the remote management controller. In other examples, the control signal may be based (at least in part) on an input at a remote interface.

In some examples, the remote management controller of the electronic module 280 may be part of a network that coordinates control of multiple pumps. A remote management controller may coordinate control of multiple pumps based (at least in part) on a variety of factors. In some examples, the remote management controller may coordinate the speed of multiple pumps to maximize or minimize a fluid temperature within the fluid lines. In some such examples, maximizing fluid temperature in a fluid line may allow the heat from the fluid to be used for other purposes, such as heating the structure within which the electronic module is located.

In other examples, the remote management controller may coordinate an increase or adjustment in flow rates of fluid in the fluid lines to increase cooling to particular components. Doing so may allow for greater flexibility in cooling electrical components that may have a greater workload than other electrical components. In some such examples, the remote management controller may also control other functionalities of the electronic module. For example, the remote management controller may adjust workloads based (at least in part) on the monitored air temperature or fluid temperature information received from controller 220 to manage workloads and thermal sensitivities of various electrical components.

Module 200 also comprises a pump connector 228 that connects to pump 270 and provides power and control signals to the pump. In some examples, module 200 may receive power via electrical module connector 210 and transmit the power via pump connector 228 to pump 270. In some such examples, electrical module connector 210 may be electrically connected to pump connector 228 via controller 220. In other such examples, connectors 210 and 228 may be directly connected or connected via a power circuit. Similarly, module 200 may receive a control signal from the electrical module or a remote management controller on the electrical module via electrical module connector 210. The control signal may be transmitted across connection 222 to controller 220 where it may be processed and then transmitted across connection 224 to pump connector 228. Similar to connection 122 of FIG. 1 and connection 222 of FIG. 2, connection 224 may comprise a wire, cable, or other electrical connection to carry an electrical signal and to electrically connect pump connector 228 to controller 220.

In some examples, pump connector 228 may comprise a USB connector. In such an example, pump connector 228 may connect to pump 270 via a USB cable having USB connectors. In other examples, pump connector 228 may comprise any suitable connection mechanism that transmits power and control signals to pump 270.

In the example of FIG. 2, module 200 further comprises a first supply connector 232 to connect a first supply fluid line 236 to provide fluid to pump 270 and a first return connector 234 to connect a first return fluid line 238 to receive fluid from pump 270. As described above in relation to first supply connector 132 and first return connector 134 of FIG. 1, first supply connector 232 and first return connector 234 mechanically connect a first supply fluid line 236 and a first return fluid line 238, respectively to module 200. First supply connector 232 and first return connector 234 may be rigid or flexible and may comprise a variety of fitting options to connect to the fluid lines and module 200, as described above in relation to FIG. 1.

In some examples, controller 220 may regulate or monitor a fluid flow rate, fluid pressure, and fluid temperature to pump 270 via first supply connector 232 or first supply fluid line 236. In other examples, controller 220 may regulate or monitor fluid flow rate, fluid pressure, and fluid temperature from pump 270 via first return connector 234 or first return fluid line 238.

Module 200 additionally comprises a second supply connector 244 to connect a second supply fluid line 248 and a second return connector 242 to connect a second return fluid line 246. As described above in relation to second supply connector 144 and second return connector 142 of FIG. 1, second supply connector 244 and second return connector 242 mechanically connect a second supply fluid line 248 and a second return fluid line 246, respectively to module 200. Second supply connector 244 and second return connector 242 may be rigid or flexible and may comprise a variety of fitting options to connect to the fluid lines and module 200, as described above in relation to FIG. 1.

In some examples, controller 220 may regulate or monitor a fluid flow rate, fluid pressure, and fluid temperature via second supply connector 244 or second supply fluid line 248. In other examples, controller 220 may regulate or monitor fluid flow rate, fluid pressure, and fluid temperature via second return connector 242 or second return fluid line 246.

In the example of FIG. 2, fluid lines 236, 238, 246, and 248 of module 200 may comprise a closed loop system. As shown, first supply fluid line 236 may be routed through pump 270 and may return to module 200 as first return fluid line 238. First return fluid line 238 may traverse module 200 and exit module 200 as second supply fluid line 248. In some examples, second supply fluid line 248 may be routed through a cooling distribution unit (CDU) 280. A cooling distribution unit, as used herein, is a unit that includes a heat exchanger. A heat exchanger may be a device for transferring heat between mediums. CDU 280 may comprise a plate heat exchanger, a microchannel heat exchanger, a closed circuit cooling tower, or any other suitable type of heat exchanger. CDU 280 may also comprise a reservoir for the fluid. In some examples, depending on whether pump 270 is on the electronic module, CDU 280 may also comprise a pump. For instance, if pump 270 is remotely located and not on the electronic module, CDU 280 may include a pump. If pump 270 is located on the electronic module, however, CDU 280 may not include a pump.

In some examples, fluid lines 236, 238, 246, and 248 of module 200 may comprise an open loop system. For instance, first supply fluid line 236 may be routed through pump 270 and return to module 200 as first return fluid line 238. First return fluid line 238 may traverse module 200 and exit module 200 as second supply fluid line 248. In some such examples, second supply fluid line 248 may be routed to an open loop cooling tower. An open loop cooling tower may involve a heat exchanger in which the mediums between which heat is being transferred are in direct contact (e.g., the fluid being cooled is in direct contact with air). The second return fluid line 246 may be routed from the open loop cooling tower back to module 200. In yet other examples, the fluid lines of module 200 may comprise an isolated loop system.

In some examples, module 200 may further include a leak detection connector 260 to connect to a leak detector 262 to detect a leak. In the examples herein, leak detection connector 260 may mechanically and electrically connect leak detector 262 to module 200. A leak detection connector, as used herein, may refer to any mechanism that mechanically and electrically connects the module to a leak detector. In some examples, leak detection connector 260 comprises a rigid connector that receives and mates with leak detector 262. In other examples, leak detection connector 260 comprises a flexible connector that connects to leak detector 262. In some examples, controller 220 may be electrically connected to leak detection connector 260 (not shown) to monitor leak detector 262. In some such examples, leak detector 262 may send signals to controller 220 indicating whether a leak has occurred.

As used herein, a leak detector may refer to any sensor that detects moisture above a certain threshold. As shown in FIG. 2, in some examples, leak detector 262 may resemble a string or line of sensors that detect a leak if fluid makes contact with any portion of leak detector 262. In other examples, a leak detector may comprise a single sensor to detect a leak if fluid makes contact with the sensor. Leak detector 262 may be positioned adjacent to the fluid lines, the electrical components of the electrical module, or any other location that a leak may occur. Leak detector 262 may also be positioned in a location to detect any flooding caused by natural disasters or any other event that may introduce moisture into or close to the electronic module. Leak detector 262 may generate a leak detection signal that is sent to electronic module 280 or the remote management controller on the electronic module 280 via the leak detection connector 260 when a leak is detected. In some examples, the leak detection signal may traverse controller 220, connection 222, and electronic module connector 210 before being received at the electronic module. In other examples, a direct path may exist between the leak detection connector 260 and electronic module connector 210.

In some examples, the components and functionalities of module 200 of FIG. 2 may be provided in combination with the components and functionalities described herein in relation to any of FIGS. 1 and 3-6.

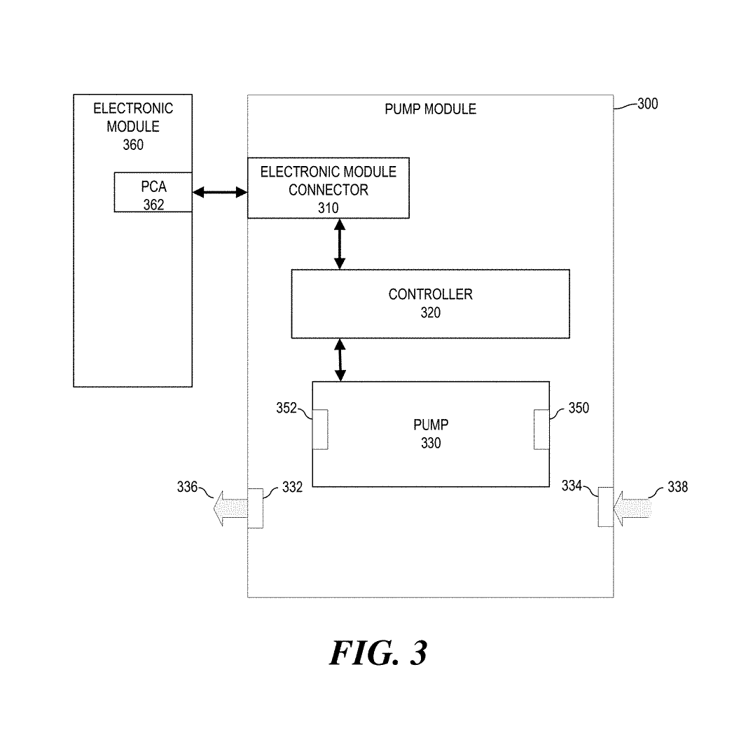

FIG. 3 illustrates a block diagram of an example pump module 300 comprising a pump 330 to receive power via an electronic module connector 310 and be controlled by a controller 320 to cool an electronic module 360. Though pump module 300 is shown separately from electronic module 360 in FIG. 3, in some examples, pump module 300 may be located on electronic module 360. In other examples, pump module 300 may be located remote from electronic module 360.

As used herein, a pump module may refer to a set of interrelated components including a pump. Pump module 300 comprises an electronic module connector 310, as described above in relation to electronic module connector 110 of FIG. 1. In the example of FIG. 3, electronic module connector 310 connects to electronic module 360. Electronic module connector 310 may comprise a USB connector such as USB connector 210a of FIG. 2 or a PCI connector such as PCI connector 210b of FIG. 2. In the example in which electronic module connector 310 comprises a USB connector, the connector may mate with a corresponding USB connector on a printed circuit assembly 362 of electronic module 360 via a USB cable. Similarly, in the example in which electronic module connector 310 comprises a PCI connector, the connector may mate with a corresponding PCI connector on printed circuit assembly 362 of electronic module 360. As described above in relation to electronic module connector 110 of FIG. 1, electronic module connector 310 of FIG. 3 may receive power from electronic module 360 and provide power to pump 330.

Pump module 300 further comprises pump 330 that receives power via electronic module connector 310. Pump 330 is electrically connected to electronic module connector 310 to receive power from the electronic module. Pump 330 may also receive a control signal from controller 320 to control the pump, as described above in relation to controller 120 of FIG. 1.

Pump 330 also comprises a pump outlet 350 through which fluid exits pump 330. In some examples, pump outlet 350 may comprise a return connector and a return fluid line, as described above in relation to FIG. 1. In some such examples, the return connector may connect the return fluid line to pump 330 and/or pump module 300. Pump 330 further comprises a pump inlet 352 through which fluid enters pump 330. In some examples, pump inlet 352 may comprise a supply connector and a supply fluid line. In some such examples, the supply connector may connect the supply fluid line to pump 330 and/or pump module 300. Pump 330 may use suction and/or pressure to move fluid through the pump outlet and pump inlet.

Pump module 300 additionally comprises a supply connector 332 to connect to a supply fluid line 336 to provide fluid to pump 330. As described above in relation to FIG. 1, a supply connector is a mechanism that mechanically connects a supply fluid line to the module. Supply connector 332 mechanically connects supply fluid line 336 to pump module 300. The supply fluid line, as described above in relation to FIG. 1, is a line that supplies fluid. Supply fluid line 336 may be made of a rigid material, a flexible material, or any other suitable material capable of carrying fluid. In some examples, supply fluid line 336 may be routed around or adjacent to electrical components of the electrical module to cool the electrical components and may provide fluid to pump 330 via pump inlet 352.

As shown in FIG. 3, pump module 300 also comprises a return connector 334 to connect to a return fluid line 338 to receive fluid from pump 330. As described above in relation to FIG. 1, a return connector is a mechanism that mechanically connects a return fluid line to the module. Return connector 334 mechanically connects return fluid line 338 to pump module 300. The return fluid line, as described above in relation to FIG. 1, is a line that returns fluid. Return fluid line 338 may be made of a rigid material, a flexible material, or any other suitable material capable of carrying fluid. In some examples, return fluid line 338 may connect to pump outlet 350 of pump 330 and may be routed through a cooling distribution unit before returning to return connector 334. In some such examples, return fluid line 338 may be connected to supply fluid line 336 through pump module 300. In some such examples, the fluid lines may be connected directly. In other examples, the fluid lines may be connected via another pump.

Pump module 300 further comprises a controller 320, as described above in relation to controller 120 of FIG. 1. Controller 320 is electrically connected to the electronic module connector 310 to control the pump. In some examples, a control signal may be received at controller 320 via electronic module connector 310, as described above in relation to FIG. 1. The control signal may regulate pump speed, fluid flow rate, fluid pressure, pump power, and the like.

In some examples, the components and functionalities of module 300 of FIG. 3 may be provided in combination with the components and functionalities described herein in relation to any of FIGS. 1-2 and 4-6.

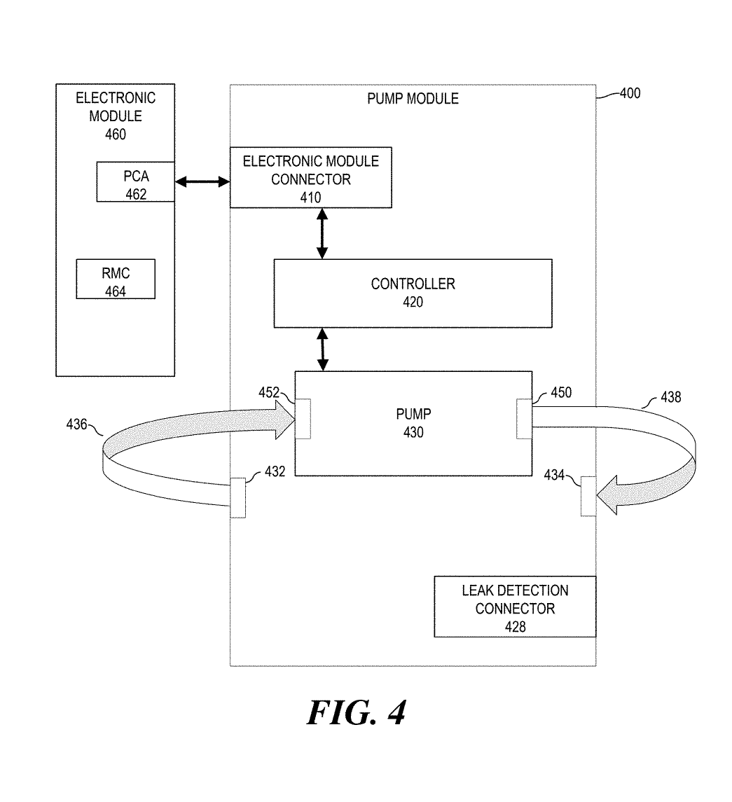

FIG. 4 illustrates a block diagram of an example pump module 400 comprising a pump 430 to receive power via an electronic module connector 410 and be controlled by a controller 420 to cool an electronic module 460. Though pump module 400 is shown separately from electronic module 460 in FIG. 4, in some examples, pump module 400 may be located on electronic module 460. In other examples, pump module 400 may be located remote from electronic module 460.

Pump module 400 comprises an electronic module connector 310, as described above in relation to electronic module connector 110 of FIG. 1. In the example of FIG. 4, electronic module connector 410 connects to electronic module 460. Electronic module connector 410 may receive power from the electronic module 460 and provide power to pump 430.

Pump module 400 further comprises pump 430 that receives power via electronic module connector 410, as described above in relation to pump 330 of FIG. 3. Pump 430 is electrically connected to electronic module connector 410 to receive power from electronic module 460. Pump 430 may also receive a control signal from controller 420 to control the pump, as described above in relation to controller 120 of FIG. 1.

As described above in relation to pump outlet 350 of FIG. 3, pump 430 comprises a pump outlet 450 through which fluid exits pump 430. As described above in relation to pump inlet 352 of FIG. 3, pump 430 further comprises a pump inlet 452 through which fluid enters pump 430. Pump 430 may use suction and/or pressure to move fluid through the pump outlet and pump inlet. Pump module 400 also comprises a supply connector 432 to connect to a supply fluid line 436 to provide fluid to pump 430 and a return connector 434 to connect to a return fluid line 438 to receive fluid from pump 430, as described above in relation to supply connector 332, supply fluid line 336, return connector 334, and return fluid line 338 of FIG. 3.

The fluid lines in the example of FIG. 4 may comprise a closed loop system, an open loop system, or an isolated loop system. In some examples, pump outlet 450 and return connector 434 may be connected via return fluid line 438. Return fluid line 438 may be routed to a cooling distribution unit, as described above in relation to CDU 280 of FIG. 2. In other examples, return fluid line 438 may be routed around or adjacent to electrical components of electrical module 460 to cool the electrical components. In yet other examples, depending on an expected temperature of the fluid in the first fluid line 436, the line may be routed away from the electrical components of electrical module 460.

In some examples, pump outlet 452 and supply connector 432 may be connected via a supply fluid line 436. Supply fluid line 436 may be routed around or adjacent to electrical components of electrical module 460 to cool the electrical components. In other examples, depending on an expected temperature of the fluid in the supply fluid line 436, the line may be routed away from the electrical components of electrical module 460. In yet other examples, supply fluid line 436 may be routed to a cooling distribution unit, as described above in relation to CDU 280 of FIG. 2.

Pump module 400 further comprises a controller 420, as described above in relation to controller 120 of FIG. 1. Controller 420 is electrically connected to the electronic module connector 410 to control pump 430. In some examples, a control signal may be received at controller 420 via electronic module connector 410, as described above in relation to FIG. 1. In other examples, a control signal may be received at controller 420 from a remote management controller 454, as described above in relation to FIG. 2. In some examples, a remote management controller may allow for control of pump 430 and/or components on electronic module 460 via a remote interface. The control signal may regulate pump speed, fluid flow rate, fluid pressure, fluid temperature, pump power, and the like.

Controller 420 may also monitor pump 430, including pump outlet 450 and pump inlet 452, as well the fluid lines and portions of electronic module 460 to track or detect fluid flow rate, fluid temperature, fluid pressure, air temperature, power consumption of pump 430, or any combination thereof. In some examples, controller 420 may monitor sensors located in and around the fluid lines, pump 430, and electronic module 460 to detect this information. In some such examples, controller 420 may send the monitored information to electronic module 460 or to remote management controller 464 on electronic module 460.

In some examples, control signals sent to controller 430 may be based (at least in part) on information monitored by controller 420 and sent to electronic module 460 and/or remote management controller 464. In other examples, control signals may be based (at least in part) on an input at a remote interface and transmitted via remote management controller 464. In some examples, the remote management controller of electronic module 460 may be part of a network that coordinates control of multiple pumps, as described above in relation to FIG. 2. In such examples, the remote management controller may coordinate flow rates and fluid pressures in the fluid lines and/or power consumption of the pumps to increase or decrease air temperatures and fluid temperatures at various pumps and throughout the network.

Pump module 400 may also comprise a leak detection connector 428, as described above in relation to leak detection connector 260 of FIG. 2. Leak detection connector 428 connects to a leak detector (not shown) to detect a leak. The leak detector may comprise a sensor or sensors to detect a leak and be positioned adjacent to the fluid lines, the electrical components of electrical module 460, or any other location that a leak may occur. When fluid makes contact with the leak detector, a leak detection signal may be sent to controller 420 to indicate that a leak has occurred. In some such examples, controller 420 may shut down pump 430. In some examples, controller 420 may also send the leak detection signal to electronic module 460 and/or remote management controller 464.

In some examples, the components and functionalities of module 400 of FIG. 4 may be provided in combination with the components and functionalities described herein in relation to any of FIGS. 1-3 and 5-6.

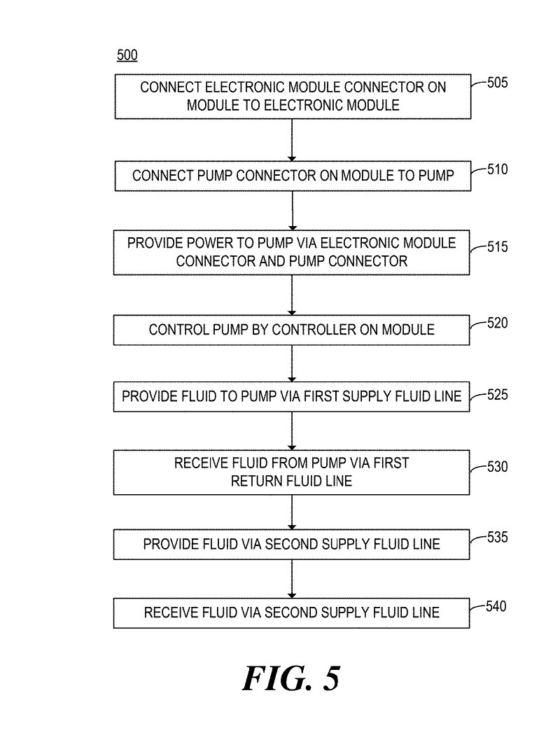

FIG. 5 is a flowchart of an example method 500 of powering and controlling a pump to cool an electronic module. Execution of method 500 is described below with reference to various features of module 200 of FIG. 2, but other suitable systems for the execution of method 500 can also be utilized (e.g., module 100 of FIG. 1, pump module 300 of FIG. 3). For instance, though the example of FIG. 2 involves a pump separate from module 200, method 500 may also be employed as in the example of FIG. 3, involving a pump module 300 that includes a pump 330. Additionally, implementation of method 500 is not limited to such examples.

In the example of FIG. 5, method 500 may be a method of module 200. At 505, electronic module connector 210 of module 200 may be connected to a corresponding connector on the electronic module, as described above in relation to electronic module connector 210 of FIG. 2. As described above, electronic module connector 210 may be a PCI connector, a USB connector, or other suitable standardized type of connector that can transmit power and control signals. In the example in which electronic module connector 210 is a PCI connector, the PCI connector is connected to a corresponding PCI connector on a printed circuit assembly of the electronic module. In the example in which electronic module connector 210 is a USB connector, the USB connector is connected to a corresponding USB connecter on a printed circuit assembly of the electronic module. Electronic module connector 210 may be connected to a corresponding connector on the printed circuit assembly of the electronic module by matching the corresponding male and female connection points of the PCI and USB connectors.

At 510, pump connector 228 of module 200 may be connected to a corresponding connector on pump 270, as described above in relation to pump connector 228 of FIG. 2. As described above, pump connector 228 may be a USB connector or other suitable connection mechanism that can transmit power and control signals to pump 270. In the example in which pump connector 228 is a USB connector, a USB cable having USB connections may be connected between module 200 at pump connector 228 and a corresponding USB connector at pump 270.

At 515, power may be provided to pump 270 via electronic module connector 210, as described above in relation to FIG. 2. In some examples, power may be transmitted via a dedicated pin or pins of the PCI connector or USB connector from the electronic module to module 200. Module 200 then provides power to the pump via pump connector 228. Power may be received at module 200 from the electronic module and transmitted to pump 270 via pump connector 228.

At 520, controller 220 of module 200 may control pump 270. As described above in relation to FIG. 2, in some examples, controller 220 may be electrically connected to electronic module connector 210 via connection 222. Controller 220 may also be electrically connected to pump connector 228 via connection 224. Controller 220 may control the pump as described above in relation to FIG. 2. In some examples, controller 220 may receive a control signal from the electronic module via electronic module connector 210 to control pump 270. In some such examples, the control signal may be transmitted via a dedicated pin or pins of the PCI connector or USB connector from the electronic module to module 200. In some examples, the control signal may be processed at controller 220 and sent to pump 270 via pump connector 228. The control signal may regulate aspects of pump operation including, but not limited to, fluid flow rate, fluid pressure, pump speed, pump power, and the like. In some such examples, based (at least in part) on the received control signal, controller 220 may increase or decrease fluid flow rate or fluid pressure in the fluid lines. In other such examples, based (at least in part) on the received control signal, controller 220 may increase or decrease the pump speed and pump power.

At 525, fluid may be provided to pump 270 via first supply fluid line 236, as described above in relation to FIG. 2. In some examples, first supply fluid line 236 may be connected to module 200 by first supply connector 232. As described above, pump 270 may use suction and/or pressure to move fluid through first supply fluid line 236. At 530, fluid may be received from pump 270 via first return fluid line 238, as described above in relation to FIG. 2. In some examples, first return fluid line 238 may be connected to module 200 by first return connector 234. At 535, fluid may be provided via second supply fluid line 248, as described above in relation to FIG. 2. In some examples, second supply fluid line 248 may be connected to module 200 by second supply connector 244. At 540, fluid may be received via second return fluid line 246, as described above in relation to FIG. 2. In some examples, second return fluid line 246 may be connected to module 200 by second return connector 242.

In some examples, as described above in relation to FIG. 2, the fluid lines may be routed around or adjacent to electrical components of the electrical module to cool the electrical components. In other examples, depending on an expected temperature of the fluid in the fluid line, the line may be routed away from the electrical components of the electrical module. In some examples, the fluid lines may comprise a closed loop. In other examples, the fluid lines may comprise an open loop. And in yet other examples, the fluid lines may comprise an isolated loop.

Although the flowchart of FIG. 5 shows a specific order of performance of certain functionalities, method 500 may not be limited to that order. For example, the functionalities shown in succession in the flowchart may be performed in a different order, may be executed concurrently or with partial concurrence, or a combination thereof. In some examples, functionalities described herein in relation to FIG. 5 may be provided in combination with functionalities described herein in relation to any of FIGS. 1-4 and 6.

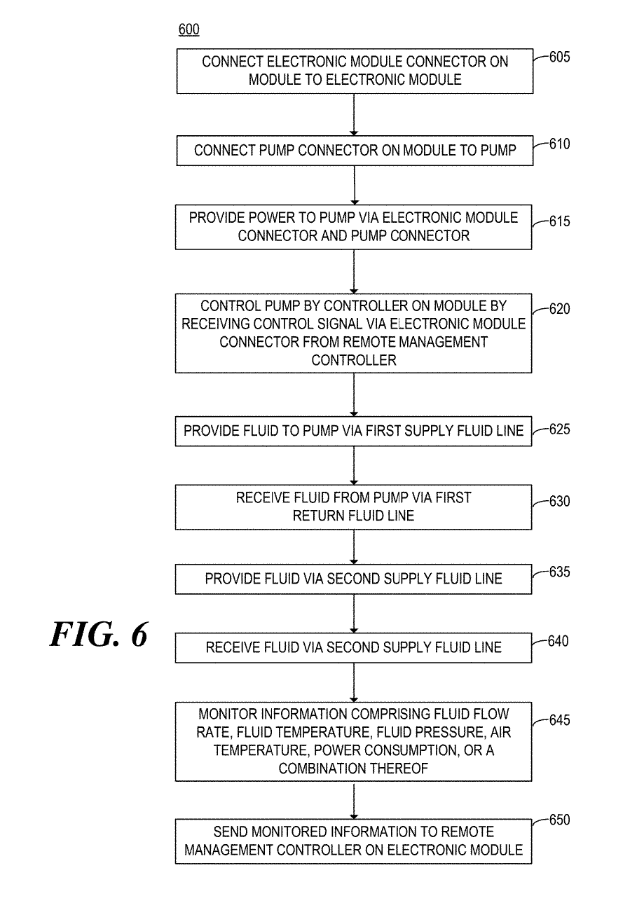

FIG. 6 is a flowchart of an example method 600 of powering and controlling a pump to cool an electronic module that includes monitoring information by a controller and sending the monitored information to a remote management controller on the electronic module. Execution of method 600 is described below with reference to module 200 of FIG. 2, but other suitable systems for the execution of method 600 can also be utilized (e.g., pump module 300 of FIG. 3). Additionally, implementation of method 600 is not limited to such examples.

In the example of FIG. 6, method 600 may be a method of module 200. At 605, similar to 505 of method 500, electronic module connector 210 of module 200 may be connected to a corresponding connector on the electronic module, as described above in relation to electronic module connector 210 of FIG. 2. At 610, similar to 510 of method 500, pump connector 228 of module 200 may be connected to a corresponding connector on pump 270, as described above in relation to pump connector 228 of FIG. 2.

At 615, similar to 515 of method 500, power may be provided to pump 270 via electronic module connector 210, as described above in relation to FIG. 2. In some examples, power may be received at module 200 from the electronic module and transmitted to pump 270 via pump connector 228, as described above in relation to FIG. 2. At 620, similar to 520 of method 500, controller 220 of module 200 may control pump 270, as described above in relation to controller 220 of FIG. 2. As described above in relation to FIG. 2, in some examples, controller 220 may be electrically connected to electronic module connector 210 via connection 222. Controller 220 may also be electrically connected to pump connector 228 via connection 224. In some examples, a control signal may be received at controller 220 via electronic module connector 210 and connection 222. In some examples, controller 220 may receive the control signal, via the electronic module connector 210, from a remote management controller, as described above in relation to FIG. 2. As described above, a remote management controller may allow for remote control of pump 270 and/or components on the electronic module via a remote interface. Controller 220 may process the received control signal and send it to pump 270 via connection 224 and pump connector 228.

At 625, similar to 525 of method 500, fluid may be provided to pump 270 via first supply fluid line 236, as described above in relation to FIG. 2. At 630, similar to 530 of method 500, fluid may be received from pump 270 via first return fluid line 238, as described above in relation to FIG. 2. At 635, similar to 535 of method 500, fluid may be provided via second supply fluid line 248, as described above in relation to FIG. 2. At 640, similar to 540 of method 500, fluid may be received via second return fluid line 246, as described above in relation to FIG. 2.

At 645, as described above in relation to FIG. 2, controller 220 of module 200 may monitor the fluid lines and pump 270 to detect and/or track fluid flow rate, fluid temperature, fluid pressure, air temperature, power consumption at pump 270, or a combination thereof. As described above, controller 220 may monitor various sensors to determine this information. At 650, controller 220 may send the monitored information to the remote management controller on the electronic module, as described above in relation to controller 220 of FIG. 2. Controller 220 may send the monitored information via connection 222 and electronic module connector 210. In some examples, the remote management controller may use this information to send control signals to pump 270 or to other pumps within the network. In other examples, controller 220 may generate a control signal based (at least in part) on, for example, the monitored information and send the control signal to pump 270 via connection 224 and pump connector 228.

Although the flowchart of FIG. 6 shows a specific order of performance of certain functionalities, method 600 may not be limited to that order. For example, the functionalities shown in succession in the flowchart may be performed in a different order, may be executed concurrently or with partial concurrence, or a combination thereof. In some examples, functionalities described herein in relation to FIG. 6 may be provided in combination with functionalities described herein in relation to any of FIGS. 1-5.

What is claimed is:

1. A module to power and control a pump to cool an electronic module comprising:
an electronic module connector to connect to a printed circuit assembly of the electronic module, wherein the connector transmits power to provide power to the pump and a control signal to control the pump;
a controller electrically connected to the connector to receive the control signal to control the pump;
a first supply connector to connect to a first supply fluid line to provide fluid to the pump;
a first return connector to connect to a first return fluid line and to receive fluid from the pump;
a second supply connector to connect to a second supply fluid line; and
a second return connector to connect to a second return fluid line.

2. The module of claim 1, wherein the electronic module connector is a peripheral component interconnect (PCI) connector or a universal serial bus (USB) connector.

3. The module of claim 1, further comprising:
a pump connector to connect to the pump to provide power and the control signal to the pump.

4. The module of claim 3, wherein the pump connector is a universal serial bus (USB) connector.

5. The module of claim 1, wherein the controller receives the control signal from a remote management controller on the electronic module that coordinates control of multiple pumps.

6. The module of claim 5, further comprising:
a leak detection connector to connect to a leak detector to detect a leak, wherein the leak detection signal is sent via the electronic module connector to the remote management controller.

7. The module of claim 1, wherein the controller monitors information comprising fluid flow rate, fluid temperature, fluid pressure, air temperature, power consumption of the pump, or a combination thereof.

8. The module of claim 1, wherein the second supply connector and the second return connector provide fluid and receive fluid from a cooling distribution unit.

9. The module of claim 1, wherein the second supply connector and the second return connector provide fluid and receive fluid from an open loop cooling tower.

10. The module of claim 1, wherein the pump is on the electronic module.

11. A pump module to cool an electronic module, the pump module comprising:
an electronic module connector to connect to the electronic module, wherein the electronic module connector is a peripheral component interconnect (PCI) connector that connects to a corresponding PCI connector or a universal serial bus (USB) connector that connects to a corresponding USB connector on a printed circuit assembly of the electronic module;
a pump that receives power via the electronic module connector, receives a control signal via a controller, has a pump outlet for pumping fluid, and has a pump inlet for receiving fluid;
a supply connector to connect to a supply fluid line to provide fluid to the pump;
a return connector to connect to a return fluid line and to receive fluid from the pump; and
the controller electrically connected to the electronic module connector to control the pump.

12. The pump module of claim 11, wherein the controller receives a control signal from a remote management controller on the electronic module to control the pump.

13. The pump module of claim 12, further comprising:
a leak detection connector to connect to a leak detector to detect a leak, wherein a leak detection signal is sent via the electronic module connector to the remote management controller.

14. The pump module of claim 12, wherein the controller monitors information comprising fluid flow rate, fluid temperature, fluid pressure, air temperature, power consumption of the pump, or a combination thereof and sends the monitored information via the electronic module connector to the remote management controller.

15. The pump module of claim 11, wherein the pump outlet and the return connector are connected via the return fluid line and the pump inlet and the supply connector are connected via the supply fluid line.

16. A method of powering and controlling a pump to cool an electronic module via a module, the method comprising:
connecting an electronic module connector on the module to the electronic module, wherein the electronic module connector is a peripheral component interconnect (PCI) connector that connects to a corresponding PCI connector or a universal serial bus (USB) connector that connects to a corresponding USB connector on a printed circuit assembly of the electronic module;
connecting a pump connector on the module to the pump;
providing power to the pump via the electronic module connector and the pump connector;
controlling the pump by a controller on the module, wherein the controller is electrically connected to the electronic module connector and the pump connector;
providing fluid to the pump via a first supply fluid line;
receiving fluid from the pump via a first return fluid line;
providing fluid via a second supply fluid line; and
receiving fluid via a second return fluid line.

17. The method of claim 16, further comprising:
monitoring information, by the controller on the module, comprising fluid flow rate, fluid temperature, fluid pressure, air temperature, power consumption of the pump, or a combination thereof.

18. The method of claim 17, further comprising:
sending the monitored information, by the controller on the module, to a remote management controller on the electronic module that coordinates control of multiple pumps.

19. The method of claim 18, wherein controlling the pump by the controller further comprises receiving a control signal at the controller via the electronic module connector from the remote management controller to control the pump.

20. The method of claim 16, wherein providing and receiving fluid via the second supply fluid line and the second return fluid line comprises providing and receiving fluid to and from a cooling distribution unit.
